(19) United States
(12) Patent Application Publication
(10) Pub. No.: US 2023/0010487 A1
(43) Pub. Date: Jan. 12, 2023

(54) ELECTROSTATIC DISCHARGE PROTECTION CIRCUIT AND CHIP

(71) Applicant: CHANGXIN MEMORY TECHNOLOGIES, INC., Hefei City (CN)

(72) Inventor: Qian XU, Hefei City (CN)

(21) Appl. No.: 17/807,040

(22) Filed: Jun. 15, 2022

Related U.S. Application Data
(63) Continuation of application No. PCT/CN2021/011340, filed on Aug. 19, 2021.

(30) Foreign Application Priority Data
Jul. 8, 2021 (CN) 202110774914.3

(51) Int. Cl. H01L 27/02; H02H 9/04

(52) U.S. Cl. CPC H01L 27/0285; H01L 27/0288; H01L 27/0255; H02H 9/046

(57) ABSTRACT

The present disclosure provides an electrostatic discharge (ESD) protection circuit and a chip. The ESD protection circuit is connected between a power supply VDD and a ground VSS, and includes a filter branch, a first inverter group, a switch transistor, a clamp transistor, a feedback transistor, and a second inverter group. The first inverter group has two terminals respectively connected to a first node and a second node. The switch transistor has a gate connected to the second node. The clamp transistor has a gate connected to a fourth node. The feedback transistor has a gate connected to the fourth node. The second inverter group has two terminals respectively connected to a third node and the fourth node.

### CROSS-REFERENCE TO RELATED APPLICATIONS

The present disclosure is a continuation application of International Patent Application No. PCT/CN2021/113406, titled “ELECTROSTATIC DISCHARGE PROTECTION CIRCUIT AND CHIP” and filed on Aug. 19, 2021, which is based on and claims the priority to Chinese Patent Application No. 202110774914.3, titled “ELECTROSTATIC DISCHARGE PROTECTION CIRCUIT AND CHIP” and filed on Jul. 8, 2021. The entire contents of International Patent Application No. PCT/CN2021/113406 and Chinese Patent Application No. 202110774914.3 are incorporated herein by reference.

### TECHNICAL FIELD

The present disclosure relates to, but is not limited to, an electrostatic discharge (ESD) protection circuit and a chip.

### BACKGROUND

As the manufacturing process of modern semiconductors is becoming more advanced, and semiconductor devices are increasingly smaller with decreasing bonding depths and thinner oxide layers, the reliability of integrated circuits (ICs) of the semiconductors is facing increasing challenges, and especially ESD protection is becoming more important. A conventional IC product generally has an ESD protection design. In a protection circuit corresponding to ESD protection in this type of product, in order to ensure that a clamp transistor can fully discharge an electrostatic current within an electrostatic occurrence time, an RC time constant is usually 0.1 μs to 1 μs. In this case, static electricity and a transient state of startup of a power supply can be distinguished. A resistor (R) is usually a diffused resistor of 5000 ohms, and a capacitor (C) is usually an NMOS capacitor of 20 picofarad. However, this type of resistor (R) and capacitor (C) occupy a relatively large layout space, and a large capacitance causes a relatively large leakage current.

### SUMMARY

A first aspect of embodiments of the present disclosure provides an electrostatic discharge protection circuit, connected between a power supply VDD and a ground VSS, where the electrostatic discharge protection circuit includes:

a filter branch, including a first node;

a first inverter group, having an input terminal and an output terminal, wherein the input terminal is connected to the first node and the output terminal is connected to a second node;

a switch transistor, connected between a third node and the ground VSS and having a gate connected to the second node;

a clamp transistor, having a gate connected to a fourth node and being used for electrostatic pulse shunting;

a feedback transistor, connected between the power supply VDD and the third node, having a gate connected to the fourth node, and being used for delaying a turn-on time of the clamp transistor; and

a second inverter group, having an input terminal and an output terminal, wherein the input terminal is connected to the third node and the output terminal is connected to the fourth node.

A second aspect of the embodiments of the present disclosure provides a chip, where one or more pins of the chip are electrically connected to the electrostatic discharge protection circuit described above.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and those of ordinary skill in the art may still derive other drawings from these accompanying drawings without creative efforts.

FIG. 1 is a schematic diagram of a first ESD protection circuit according to an exemplary embodiment.

FIG. 2 is a schematic diagram of a second ESD protection circuit according to an exemplary embodiment.

FIG. 3 is a schematic diagram of a third ESD protection circuit according to an exemplary embodiment.

FIG. 4 is a schematic diagram of a fourth ESD protection circuit according to an exemplary embodiment.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that without conflict, the embodiments in the present disclosure and features in the embodiments may be combined with each other.

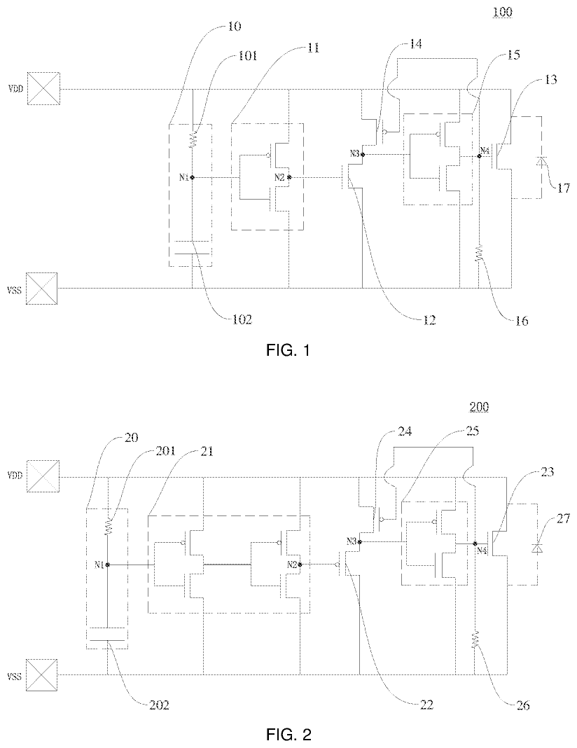

FIG. 1 to FIG. 4 are each a schematic diagram of an ESD protection circuit according to the present disclosure.

According to an embodiment of the present disclosure, referring to FIG. 1, the ESD protection circuit 100 is connected between a power supply VDD and a ground VSS, and includes: a filter branch 10, a first inverter group 11, a switch transistor 12, a clamp transistor 13, a feedback transistor 14, and a second inverter group 15.

The filter branch 10 includes a filter resistor 101 and a filter capacitor 102. The filter resistor 101 and the filter capacitor 102 are connected in series between the power supply VDD and the ground VSS, and a first node N1 is provided on a path therebetween. The filter resistor 101 has one terminal connected to the power supply VDD and the other terminal connected to the first node N1. The filter capacitor 102 has one terminal connected to the ground VSS and the other terminal connected to the first node N1.

An input terminal of the first inverter group 11 is connected to the first node N1, and an output terminal of the first inverter group 11 is connected to a second node N2.

The switch transistor 12 has a first terminal, a second terminal, and a third terminal. The first terminal of the switch transistor 12 is connected to a third node N3, the second terminal is connected to the ground VSS, and the third terminal, namely, a gate is connected to the second node N2.

The clamp transistor 13 has a first terminal, a second terminal, and a third terminal. The first terminal of the clamp transistor 13 is connected to the power supply VDD, the second terminal is connected to the ground VSS, and the third terminal, namely, a gate is connected to a fourth node N4, for implementing electrostatic pulse shunting.

The feedback transistor 14 has a first terminal, a second terminal, and a third terminal. The first terminal of the feedback transistor 14 is connected to the power supply VDD, the second terminal is connected to the third node N3, and the third terminal, namely, a gate is connected to the fourth node N4. The feedback transistor 14 is used for delaying a turn-on time of the clamp transistor 13.

An input terminal of the second inverter group 15 is connected to the third node N3, and an output terminal of the second inverter group 15 is connected to the fourth node N4.

The ESD protection circuit 100 in this embodiment further includes a first resistor 16. One terminal of the first resistor 16 is connected to the fourth node N4, and the other terminal of the first resistor 16 is connected to the ground VSS, such that the clamp transistor 13 is at a low potential or at a high potential, and thus the clamp transistor 13 is in an off state.

The ESD protection circuit in this embodiment further includes a parasitic diode 17. The parasitic diode 17 has one terminal connected to the power supply VDD and the other terminal connected to the ground VSS, and is connected in parallel to the clamp transistor 13, for conducting the path between the ground VSS and the power supply VDD.

In this embodiment, the clamp transistor 13 is an N-type transistor, and the first terminal of the clamp transistor 13 is a drain and connected to the power supply VDD; the second terminal thereof is a source and connected to the ground VSS; and the third terminal thereof is a gate and connected to the fourth node N4.

The feedback transistor 14 is a P-type transistor, and the first terminal of the feedback transistor 14 is a source and connected to the power supply VDD; the second terminal thereof is a drain and connected to the third node N3; and the third terminal thereof is a gate and connected to the fourth node N4.

The switch transistor 12 is an N-type transistor, and the first terminal of the switch transistor 12 is a drain and connected to the third node N3; the second terminal thereof is a source and connected to the ground VSS; and the third terminal thereof is a gate and connected to the second node N2.

When the clamp transistor 13 is an N-type transistor, the feedback transistor 14 is a P-type transistor, and the switch transistor 12 is an N-type transistor, both the first inverter group 11 and the second inverter group 15 include an odd number of inverters, such as one inverter, or three or five inverters. In this embodiment, for example, both the first inverter group 11 and the second inverter group 15 include one inverter.

The first inverter group 11 and the second inverter group 15 both include one P-type transistor and one N-type transistor. A gate of the P-type transistor in either inverter is connected to a gate of an N-type transistor in the inverter as an input terminal, and a drain of the P-type transistor is connected to a drain of the N-type transistor as an output terminal.

A working state of the ESD protection circuit 100 in this embodiment of the present disclosure may be divided into a normal working state and an ESD occurrence state. The ESD occurrence state of the ESD protection circuit 100 in this embodiment includes a PS mode and an NS mode. The PS mode means that when the power supply VDD is floating, ESD of a relative positive voltage discharges to the ground VSS at a certain input pin. The NS mode means that when the power supply VDD is floating, ESD of a relative negative voltage discharges to the ground VSS at a certain input pin. ESD processes in the PS mode and the NS mode are respectively used as an example for description.

When the power supply VDD is turned on and works normally, the fourth node N4 is connected to the ground VSS through the first resistor 16. In this case, the fourth node N4 is at a low potential, the clamp transistor 13 is in a cutoff state, and the ESD protection circuit is turned off. In the foregoing state, the feedback transistor 14 is turned on, and the third node N3 is at a high potential. After the high potential passes through the second inverter group 15, the P-type transistor in the second inverter group 15 is in a cutoff state, and the N-type transistor in the second inverter group 15 is in an on state, thereby further ensuring that the fourth node N4 is at a low potential, further ensuring that the clamp transistor 13 is in a cutoff state, and further ensuring that the ESD protection circuit 100 is turned off.

When static electricity occurs in the PS mode, the filter branch 10 constituted by the filter resistor 101 and the filter capacitor 102 causes the first node N1 to be at a low potential. After the low potential of the first node N1 undergoes phase inversion in the first inverter group 11, the P-type transistor in the first inverter group 11 is in an on state, and the N-type transistor in the first inverter group 11 is in a cutoff state, such that the second node N2 is at a high potential. In this case, the switch transistor 12 is turned on, such that the third node N3 is at a low potential. After the low potential of the third node N3 undergoes phase inversion in the second inverter group 15, the P-type transistor in the second inverter group 15 is in an on state, and the N-type transistor in the second inverter group 15 is in a cutoff state, such that the fourth node N4 is at a high potential, and the clamp transistor 13 is turned on to start discharging an electrostatic current.

Within an electrostatic action time, the potential of the first node N1 gradually rises, in an attempt to turn off the P-type transistor in the first inverter group 11 and in an attempt to turn on the N-type transistor in the first inverter group 11, thus in an attempt to raise the potential of the second node N2 to a low potential to turn off the switch transistor 12. However, in this case, because the fourth node N4 is at a high potential, and the feedback transistor 14 is in a cutoff state, the third node N3 cannot be raised to the high potential through the feedback transistor 14. In this way, the third node N3 can be maintained at a low potential for a longer time, thereby ensuring that the fourth node N4 is maintained at the high potential for a longer time. In this way, a feedback circuit formed by the feedback transistor 14 can maintain the fourth node N4 at the high potential for a longer within an electrostatic action time, to effectively ensure that the clamp transistor 13 is turned on and discharge an electrostatic current within the electrostatic action time.

When static electricity occurs in the NS mode, the clamp transistor 13 is in an on state. In this case, an electrostatic current is discharged by the parasitic diode 17 connected in parallel to the clamp transistor 13, and after the electrostatic discharge, the current flows from the ground VSS to the power supply VDD through the parasitic diode 17.

The ESD protection circuit in this embodiment can still effectively extend an electrostatic discharge time even if a capacitor with a relatively small capacity is used and an RC time constant is reduced, thereby preventing the electrostatic current from damaging an electronic device, reducing areas occupied by the capacitor and the resistor in a semiconductor layout, and further effectively reducing a leakage current.

According to an embodiment of the present disclosure, referring to FIG. 2, the ESD protection circuit 200 is connected between a power supply VDD and a ground VSS, and includes: a filter branch 20, a first inverter group 21, a switch transistor 22, a clamp transistor 23, a feedback transistor 24, and a second inverter group 25.

The filter branch 20 includes a filter resistor 201 and a filter capacitor 202. The filter resistor 201 and the filter capacitor 202 are connected in series between the power supply VDD and the ground VSS, and a first node N1 is provided on a path therebetween. The filter resistor 201 has one terminal connected to the power supply VDD and the other terminal connected to the first node N1. The filter capacitor 202 has one terminal connected to the ground VSS and the other terminal connected to the first node N1.

An input terminal of the first inverter group 21 is connected to the first node N1, and an output terminal of the first inverter group 21 is connected to a second node N2.

The switch transistor 22 has a first terminal, a second terminal, and a third terminal. The first terminal of the switch transistor 22 is connected to a third node N3, the second terminal is connected to the ground VSS, and the third terminal, namely, a gate is connected to the second node N2.

The clamp transistor 23 has a first terminal, a second terminal, and a third terminal. The first terminal of the clamp transistor 23 is connected to the power supply VDD, the second terminal is connected to the ground VSS, and the third terminal, namely, a gate is connected to a fourth node N4, for implementing electrostatic pulse shunting.

The feedback transistor 24 has a first terminal, a second terminal, and a third terminal. The first terminal of the feedback transistor 24 is connected to the power supply VDD, the second terminal is connected to the third node N3, and the third terminal, namely, a gate is connected to the fourth node N4, for delaying a turn-on time of the clamp transistor 23.

An input terminal of the second inverter group 25 is connected to the third node N3, and an output terminal of the second inverter group 25 is connected to the fourth node N4.

The ESD protection circuit 200 in this embodiment further includes a first resistor 26. One terminal of the first resistor 26 is connected to the fourth node N4, and the other terminal of the first resistor 26 is connected to the ground VSS, such that the clamp transistor 23 is at a low potential or at a high potential, and thus the clamp transistor 23 is in an off state.

The ESD protection circuit 200 in this embodiment further includes a parasitic diode 27. The parasitic diode 27 has one terminal connected to the power supply VDD and the other terminal connected to the ground VSS, and is connected in parallel to the clamp transistor 23, for conducting the path between the ground VSS and the power supply VDD.

In this embodiment, the clamp transistor 23 is an N-type transistor, and the first terminal of the clamp transistor 23 is a drain and connected to the power supply VDD; the second terminal thereof is a source and connected to the ground VSS; and the third terminal thereof is a gate and connected to the fourth node N4.

The feedback transistor 24 is a P-type transistor, and the first terminal of the feedback transistor 24 is a source and connected to the power supply VDD; the second terminal thereof is a drain and connected to the third node N3; and the third terminal thereof is a gate and connected to the fourth node N4.

The switch transistor 22 is a P-type transistor, and the first terminal of the switch transistor 22 is a drain and connected to the third node N3; the second terminal thereof is a source and connected to the ground VSS; and the third terminal thereof is a gate and connected to the second node N2.

When the clamp transistor 23 is an N-type transistor, the feedback transistor 24 is a P-type transistor, and the switch transistor 22 is a P-type transistor, the first inverter group 21 includes an even number of inverters, such as two, four, or six inverters, and the second inverter group 25 includes an odd number of inverters, such as one inverter, or three or five inverters. In this embodiment, for example, the first inverter group 21 includes two inverters connected in series, and the second inverter group 25 includes one inverter.

The two inverters in the first inverter group 21 and the one inverter in the second inverter group 25 each include one P-type transistor and one N-type transistor. A gate of the P-type transistor in either inverter is connected to a gate of an N-type transistor in the inverter as an input terminal, and a drain of the P-type transistor is connected to a drain of the N-type transistor as an output terminal.

A working state of the ESD protection circuit 200 in this embodiment of the present disclosure may be divided into a normal working state and an ESD occurrence state. The ESD occurrence state of the ESD protection circuit 200 in this embodiment includes a PS mode and an NS mode. The PS mode means that when the power supply VDD is floating, ESD of a relative positive voltage discharges to the ground VSS at a certain input pin. The NS mode means that when the power supply VDD is floating, ESD of a relative negative voltage discharges to the ground VSS at a certain input pin. ESD processes in the PS mode and the NS mode are respectively used as an example for description.

When the power supply is turned on and works normally, the fourth node N4 is connected to the ground VSS through the first resistor 26. In this case, the fourth node N4 is at a low potential, the clamp transistor 23 is in a cutoff state, and the ESD protection circuit is turned off. In the foregoing state, the feedback transistor 24 is turned on, and the third node N3 is at a high potential. After the high potential passes through the second inverter group 25, the P-type transistor in the second inverter group 25 is in a cutoff state, and the N-type transistor in the second inverter group 25 is in an on state, thereby further ensuring that the fourth node N4 is at a low potential, further ensuring that the clamp transistor 23 is in a cutoff state, and further ensuring that the ESD protection circuit 200 is turned off.

When static electricity occurs in the PS mode, the filter branch 20 constituted by the filter resistor 201 and the filter capacitor 202 causes the first node N1 to be at a low potential. After the low potential of the first node N1 undergoes two phase inversions by the two inverters in the first inverter group 21, the second node N2 is at the low potential. In this case, the switch transistor 22 is turned on, such that the third node N3 is at a low potential. After the low potential of the third node N3 undergoes phase inversion in the second inverter group 25, the P-type transistor in the second inverter group 25 is in an on state, and the N-type transistor in the second inverter group 25 is in a cutoff state, such that the fourth node N4 is at a high potential, and the clamp transistor is turned on to start discharging an electrostatic current.

Within an electrostatic action time, when the potential of the first node N1 gradually rises, after the two phase inversions in the first inverter group 21, the potential of the second node N2 is raised to a high potential to cause the switch transistor 22 to be in a cutoff state. In this case, because the fourth node N4 is at a high potential, and the feedback transistor 24 is in a cutoff state, the third node N3 cannot be raised to the high potential. In this way, the third node N3 can be maintained at a low potential for a longer time, thereby ensuring that the fourth node N4 is maintained at the high potential for a longer time, and that the fourth node N4 is maintained at the low potential for a longer time within the electrostatic action time, thus effectively ensuring that the clamp transistor 23 is turned on and discharge an electrostatic current within the electrostatic action time.

When static electricity occurs in the NS mode, the clamp transistor 23 is in an on state. In this case, an electrostatic current is discharged by the parasitic diode 27 connected in parallel to the clamp transistor 23, and after the electrostatic discharge, the current flows from the ground VSS to the power supply VDD through the parasitic diode 27.

The ESD protection circuit in this embodiment can still effectively extend an electrostatic discharge time even if a capacitor with a relatively small capacity is used and an RC time constant is reduced, thereby preventing the electrostatic current from damaging an electronic device, reducing areas occupied by the capacitor and the resistor in a semiconductor layout, and further effectively reducing a leakage current.

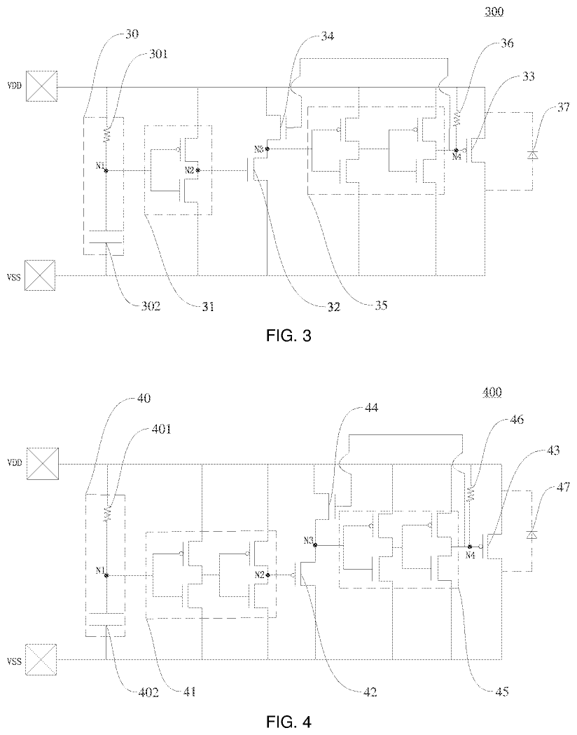

According to an embodiment of the present disclosure, referring to FIG. 3, the ESD protection circuit 300 is connected between a power supply VDD and a ground VSS, and includes: a filter branch 30, a first inverter group 31, a switch transistor 32, a clamp transistor 33, a feedback transistor 34, and a second inverter group 35.

The filter branch 30 includes a filter resistor 301 and a filter capacitor 302. The filter resistor 301 and the filter capacitor 302 are connected in series between the power supply VDD and the ground VSS, and a first node N1 is provided on a path therebetween. The filter resistor 301 has one terminal connected to the power supply VDD and the other terminal connected to the first node N1. The filter capacitor 302 has one terminal connected to the ground VSS and the other terminal connected to the first node N1.

An input terminal of the first inverter group 31 is connected to the first node N1, and an output terminal of the first inverter group 31 is connected to a second node N2.

The switch transistor 32 has a first terminal, a second terminal, and a third terminal. The first terminal of the switch transistor 32 is connected to a third node N3, the second terminal is connected to the ground VSS, and the third terminal, namely, a gate is connected to the second node N2.

The clamp transistor 33 has a first terminal, a second terminal, and a third terminal. The first terminal of the clamp transistor 33 is connected to the power supply VDD, the second terminal is connected to the ground VSS, and the third terminal, namely, a gate is connected to a fourth node N4, for implementing electrostatic pulse shunting.

The feedback transistor 34 has a first terminal, a second terminal, and a third terminal. The first terminal of the feedback transistor 34 is connected to the power supply VDD, the second terminal is connected to the third node N3, and the third terminal, namely, a gate is connected to the fourth node N4, for delaying a turn-on time of the clamp transistor 33.

An input terminal of the second inverter group 35 is connected to the third node N3, and an output terminal of the second inverter group 35 is connected to the fourth node N4.

The ESD protection circuit 300 in this embodiment further includes a second resistor 36. One terminal of the second resistor 36 is connected to the fourth node N4, and the other terminal of the second resistor 36 is connected to the power supply VDD, such that the clamp transistor 33 is at a low potential or at a high potential, and thus the clamp transistor 33 is in an off state.

The ESD protection circuit 300 in this embodiment further includes a parasitic diode 37. The parasitic diode 37 has one terminal connected to the power supply VDD and the other terminal connected to the ground VSS, and is connected in parallel to the clamp transistor 33, for conducting the path between the ground VSS and the power supply VDD.

In this embodiment, the clamp transistor 33 is a P-type transistor, and the first terminal of the clamp transistor 33 is a drain and connected to the power supply VDD; the second terminal thereof is a source and connected to the ground VSS; and the third terminal thereof is a gate and connected to the fourth node N4.

The feedback transistor 34 is an N-type transistor, and the first terminal of the feedback transistor 34 is a source and connected to the power supply VDD; the second terminal thereof is a drain and connected to the third node N3; and the third terminal thereof is a gate and connected to the fourth node N4.

The switch transistor 32 is an N-type transistor, and the first terminal of the switch transistor 32 is a drain and connected to the third node N3; the second terminal thereof is a source and connected to the ground VSS; and the third terminal thereof is a gate and connected to the second node N2.

When the clamp transistor 33 is an P-type transistor, the feedback transistor 34 is an N-type transistor, and the switch transistor 32 is an N-type transistor, the first inverter group 31 includes an odd number of inverters, such as one inverter, or three or five inverters, and the second inverter group 35 includes an even number of inverters, such as two, four, or six inverters. In this embodiment, for example, the first inverter group 31 includes one inverter, and the second inverter group 35 includes two inverters connected in series.

The one inverter in the first inverter group 31 and the two inverters in the second inverter group 35 each include one P-type transistor and one N-type transistor. A gate of the P-type transistor in either inverter is connected to a gate of an N-type transistor in the inverter as an input terminal, and a drain of the P-type transistor is connected to a drain of the N-type transistor as an output terminal.

A working state of the ESD protection circuit 300 in this embodiment of the present disclosure may be divided into a normal working state and an ESD occurrence state. The ESD occurrence state of the ESD protection circuit 300 in this embodiment includes a PS mode and an NS mode. The PS mode means that when the power supply VDD is floating, ESD of a relative positive voltage discharges to the ground VSS at a certain input pin. The NS mode means that when the power supply VDD is floating, ESD of a relative negative voltage discharges to the ground VSS at a certain input pin. ESD processes in the PS mode and the NS mode are respectively used as an example for description.

When the power supply is turned on and works normally, the fourth node N4 is connected to the power supply VDD through the second resistor 36. In this case, the fourth node N4 is at a high potential, the clamp transistor 33 is in a cutoff state, and the ESD protection circuit is turned off. In the foregoing state, the feedback transistor 34 is turned on, and the third node N3 is at a high potential. After the high potential undergoes the two phase inversions in the second inverter group 35, the fourth node N4 is caused to maintain at the high potential, to further ensure that the clamp transistor 33 is in a cutoff state, and further ensure that the ESD protection circuit 300 is turned off.

When static electricity occurs in the PS mode, the filter branch 30 constituted by the filter resistor 301 and the filter capacitor 302 causes the first node N1 to be at a low potential. After the low potential of the first node N1 undergoes the phase inversion in the first inverter group 31, the second node N2 is at a high potential. In this case, the switch transistor 32 is turned on, such that the third node N3 is at a low potential. After the low potential of the third node N3 undergoes the two phase inversions in the second inverter group 35, the fourth node N4 is at the low potential, and the clamp transistor 33 is turned on to start discharging an electrostatic current.

Within an electrostatic action time, when the potential of the first node N1 gradually rises, after the phase inversion in the first inverter group 31, the potential of the second node N2 is reduced to a low potential to cause the switch transistor 32 to be in a cutoff state. In this case, because the fourth node N4 is at a low potential, and the feedback transistor 34 is in a cutoff state, the third node N3 cannot be raised to the high potential.

In this way, the third node N3 can be maintained at a low potential for a longer time, thereby ensuring that the fourth node N4 is maintained at the low potential for a longer time. The fourth node N4 is maintained at the low potential for a longer within an electrostatic action time, to effectively ensure that the clamp transistor 33 is turned on and discharge an electrostatic current within the electrostatic action time.

When static electricity occurs in the NS mode, the clamp transistor 33 is in an on state. In this case, an electrostatic current is discharged by the parasitic diode 37 connected in parallel to the clamp transistor 33, and after the electrostatic discharge, the current flows from the ground VSS to the power supply VDD through the parasitic diode 37.

The ESD protection circuit in this embodiment can still effectively extend an electrostatic discharge time even if a capacitor with a relatively small capacity is used and an RC time constant is reduced, thereby preventing the electrostatic current from damaging an electronic device, reducing areas occupied by the capacitor and the resistor in a semiconductor layout, and further effectively reducing a leakage current.

According to an embodiment of the present disclosure, referring to FIG. 4, the ESD protection circuit 400 is connected between a power supply VDD and a ground VSS, and includes: a filter branch 40, a first inverter group 41, a switch transistor 42, a clamp transistor 43, a feedback transistor 44, and a second inverter group 45.

The filter branch 40 includes a filter resistor 401 and a filter capacitor 402. The filter resistor 401 and the filter capacitor 402 are connected in series between the power supply VDD and the ground VSS, and a first node N1 is provided on a path therebetween. The filter resistor 401 has one terminal connected to the power supply VDD and the other terminal connected to the first node N1. The filter capacitor 402 has one terminal connected to the ground VSS and the other terminal connected to the first node N1.

An input terminal of the first inverter group 41 is connected to the first node N1, and an output terminal of the first inverter group 41 is connected to a second node N2.

The switch transistor 42 has a first terminal, a second terminal, and a third terminal. The first terminal of the switch transistor 42 is connected to a third node N3, the second terminal is connected to the ground VSS, and the third terminal, namely, a gate is connected to the second node N2.

The clamp transistor 43 has a first terminal, a second terminal, and a third terminal. The first terminal of the clamp transistor 43 is connected to the power supply VDD, the second terminal is connected to the ground VSS, and the third terminal, namely, a gate is connected to a fourth node N4, for implementing electrostatic pulse shunting.

The feedback transistor 44 has a first terminal, a second terminal, and a third terminal. The first terminal of the feedback transistor 44 is connected to the power supply VDD, the second terminal is connected to the third node N3, and the third terminal, namely, a gate is connected to the fourth node N4, for delaying a turn-on time of the clamp transistor 43.

An input terminal of the second inverter group 45 is connected to the third node N3, and an output terminal of the second inverter group 45 is connected to the fourth node N4.

The ESD protection circuit in this embodiment further includes a second resistor 46. One terminal of the second resistor 46 is connected to the fourth node N4, and the other terminal of the second resistor 46 is connected to the power supply VDD, such that the clamp transistor 43 is at a low potential or at a high potential, and thus the clamp transistor 43 is in an off state.

The ESD protection circuit in this embodiment further includes a parasitic diode 47. The parasitic diode 47 has one terminal connected to the power supply VDD and the other terminal connected to the ground VSS, and is connected in parallel to the clamp transistor 43, for conducting the path between the ground VSS and the power supply VDD.

In this embodiment, the clamp transistor 43 is a P-type transistor, and the first terminal of the clamp transistor 43 is a drain and connected to the power supply VDD; the second terminal thereof is a source and connected to the ground VSS; and the third terminal thereof is a gate and connected to the fourth node N4.

The feedback transistor 44 is an N-type transistor, and the first terminal of the feedback transistor 44 is a source and connected to the power supply VDD; the second terminal thereof is a drain and connected to the third node N3; and the third terminal thereof is a gate and connected to the fourth node N4.

The switch transistor 42 is a P-type transistor, and the first terminal of the switch transistor 42 is a drain and connected to the third node N3; the second terminal thereof is a source and connected to the ground VSS; and the third terminal thereof is a gate and connected to the second node N2.

When the clamp transistor 43 is a P-type transistor, the feedback transistor 44 is an N-type transistor, and the switch transistor 42 is a P-type transistor, the first inverter group 41 includes an even number of inverters, and the second inverter group 45 includes an even number of inverters, such as two, four, or six inverters. In this embodiment, for example, the first inverter group 41 includes two inverters connected in series, and the second inverter group 45 includes two inverters connected in series.

The two inverters in the first inverter group 41 and the two inverters in the second inverter group 45 each include one P-type transistor and one N-type transistor. A gate of the P-type transistor in either inverter is connected to a gate of an N-type transistor in the inverter as an input terminal, and a drain of the P-type transistor is connected to a drain of the N-type transistor as an output terminal.

A working state of the ESD protection circuit 400 in this embodiment of the present disclosure may be divided into a normal working state and an ESD occurrence state. The ESD occurrence state of the ESD protection circuit 200 in this embodiment includes a PS mode and an NS mode. The PS mode means that when the power supply VDD is floating, ESD of a relative positive voltage discharges to the ground VSS at a certain input pin. The NS mode means that when the power supply VDD is floating, ESD of a relative negative voltage discharges to the ground VSS at a certain input pin. ESD processes in the PS mode and the NS mode are respectively used as an example for description.

When the power supply is turned on and works normally, the fourth node N4 is connected to the power supply VDD through the second resistor 46. In this case, the fourth node N4 is at a high potential, the clamp transistor 43 is in a cutoff state, and the ESD protection circuit is turned off. In the foregoing state, the feedback transistor 44 is turned on, and the third node N3 is at a high potential. After the high potential undergoes the two phase inversions in the second inverter group 45, the fourth node N4 is caused to maintain at the high potential, to further ensure that the clamp transistor 43 is in a cutoff state, and further ensure that the ESD protection circuit 400 is turned off.

When static electricity occurs in the PS mode, the filter branch 40 constituted by the filter resistor 401 and the filter capacitor 402 causes the first node N1 to be at a low potential. After the low potential of the first node N1 undergoes the two phase inversions in the first inverter group 41, the second node N2 is at the low potential. In this case, the switch transistor 42 is turned on, such that the third node N3 is at a low potential. After the low potential of the third node N3 undergoes the two phase inversions in the second inverter group 45, the fourth node N4 is at the low potential, and the clamp transistor 43 is turned on to start discharging an electrostatic current.

Within an electrostatic action time, when the potential of the first node N1 gradually rises, after the two phase inversions in the first inverter group 41, the potential of the second node N2 is raised to a high potential to cause the switch transistor 42 to be in a cutoff state. In this case, because the fourth node N4 is at a low potential, and the feedback transistor 44 is in a cutoff state, the third node N3 cannot be raised to the high potential. In this way, the third node N3 can be maintained at a low potential for a longer time, thereby ensuring that the fourth node N4 is maintained at the low potential for a longer time, and that the fourth node N4 is maintained at the low potential for a longer time within the electrostatic action time, thus effectively ensuring that the clamp transistor 43 is turned on and discharge an electrostatic current within the electrostatic action time.

When static electricity occurs in the NS mode, the clamp transistor 43 is in an on state. In this case, an electrostatic current is discharged by the parasitic diode 47 connected in series with the clamp transistor 43, and after the electrostatic discharge, the current flows from the ground VSS to the power supply VDD through the parasitic diode 47.

The ESD protection circuit in this embodiment can still effectively extend an electrostatic discharge time even if a capacitor with a relatively small capacity is used and an RC time constant is reduced, thereby preventing the electrostatic current from damaging an electronic device, reducing areas occupied by the capacitor and the resistor in a semiconductor layout, and further effectively reducing a leakage current.

According to another aspect of the present disclosure, a chip is provided, where one or more pins of the chip are electrically connected to the ESD protection circuit in the foregoing embodiments.

In the ESD protection circuit of the present disclosure, a feedback transistor is provided between a third node and a fourth node, to control and extend a turn-on time of the ESD protection circuit during electrostatic action, such that a capacitor with a relatively small value can be used, thereby effectively resolving a problem of a relatively high leakage current caused by a relatively large capacitor. In addition, use of a relatively small capacitor can reduce an RC time constant, thereby reducing an overall layout area, and improving performance of the ESD protection circuit. In addition, the ESD protection circuit of the present disclosure implements ESD protection in the PS mode and the NS mode, and effectively improves an electrostatic protection capability of a semiconductor component product, and the ESD protection circuit does not affect performance and normal functions of the chip, thereby effectively improving reliability and competitiveness of the semiconductor component product.

The embodiments or implementations of this specification are described in a progressive manner, and each embodiment focuses on differences from other embodiments. The same or similar parts between the embodiments may refer to each other.

In the descriptions of this specification, a description with reference to the term “one implementation”, “some implementations”, “an exemplary implementation”, “an example”, “a specific example”, “some examples”, or the like means that a specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

Finally, it should be noted that the foregoing embodiments are used only to explain the technical solutions of the present disclosure, but are not intended to limit the present disclosure. Although the present disclosure has been described in detail with reference to the foregoing embodiments, those of ordinary skill in the art should understand that they can still modify the technical solutions described in the foregoing embodiments, or make equivalent substitutions on some or all technical features therein. The modifications or substitutions do not make the essence of the corresponding technical solutions deviate from the spirit and scope of the technical solutions of the embodiments of the present disclosure.

### INDUSTRIAL APPLICABILITY

According to the ESD protection circuit and chip provided in the embodiments of the present disclosure, a feedback transistor is provided at the third node and the fourth node, and a turn-on time of a clamp transistor is delayed, such that an electrostatic pulse shunting time of the clamp transistor is effectively increased, an RC time constant and a layout area are reduced, and performance of an ESD protection circuit is improved, thereby resolving a problem of relatively large leakage current caused by a relatively large capacitance value and a problem of increased layout area caused by a relatively large RC time constant, and improving a capability of ESD protection for a product.

1. An electrostatic discharge protection circuit, connected between a power supply VDD and a ground VSS, and comprising:
a filter branch, comprising a first node;
a first inverter group, having an input terminal and an output terminal, wherein the input terminal is connected to the first node and the output terminal is connected to a second node;
a switch transistor, connected between a third node and the ground VSS and having a gate connected to the second node;
a clamp transistor, having a gate connected to a fourth node and being used for electrostatic pulse shunting;
a feedback transistor, connected between the power supply VDD and the third node, having a gate connected to the fourth node, and being used for delaying a turn-on time of the clamp transistor; and
a second inverter group, having an input terminal and an output terminal, wherein the input terminal is connected to the third node and the output terminal is connected to the fourth node.

2. The electrostatic discharge protection circuit according to claim 1, wherein the clamp transistor is an N-type transistor;
the feedback transistor is a P-type transistor; and
the switch transistor is an N-type transistor.

3. The electrostatic discharge protection circuit according to claim 2, wherein the first inverter group comprises an odd number of inverters; and
the second inverter group comprises an odd number of inverters.

4. The electrostatic discharge protection circuit according to claim 1, wherein the clamp transistor is an N-type transistor;
the feedback transistor is a P-type transistor; and
the switch transistor is a P-type transistor.

5. The electrostatic discharge protection circuit according to claim 4, wherein the first inverter group comprises an even number of inverters; and
the second inverter group comprises an odd number of inverters.

6. The electrostatic discharge protection circuit according to claim 2, wherein the electrostatic discharge protection circuit further comprises a first resistor, connected between the fourth node and the ground VSS.

7. The electrostatic discharge protection circuit according to claim 1, wherein the clamp transistor is a P-type transistor;
the feedback transistor is an N-type transistor; and
the switch transistor is an N-type transistor.

8. The electrostatic discharge protection circuit according to claim 7, wherein the first inverter group comprises an odd number of inverters; and
the second inverter group comprises an even number of inverters.

9. The electrostatic discharge protection circuit according to claim 1, wherein the clamp transistor is a P-type transistor;
the feedback transistor is an N-type transistor; and
the switch transistor is a P-type transistor.

10. The electrostatic discharge protection circuit according to claim 9, wherein the first inverter group comprises an even number of inverters; and
the second inverter group comprises an even number of inverters.

11. The electrostatic discharge protection circuit according to claim 7, wherein the electrostatic discharge protection circuit further comprises a second resistor, connected between the fourth node and the power supply VDD.

12. The electrostatic discharge protection circuit according to claim 1, wherein the electrostatic discharge protection circuit further comprises a parasitic diode, connected between the power supply VDD and the ground VSS, and the parasitic diode is used for conducting a path between the ground VSS and the power supply VDD.

13. The electrostatic discharge protection circuit according to claim 1, wherein the filter branch comprises:
a filter resistor, connected between the power supply VDD and the first node; and
a filter capacitor, connected between the ground VSS and the first node.

14. The electrostatic discharge protection circuit according to claim 1, wherein inverters in the first inverter group or the second inverter group comprise:
one P-type transistor; and
one N-type transistor, connected in series with the P-type transistor, wherein
a gate of the P-type transistor is connected to a gate of the N-type transistor as an input terminal; and
a drain of the P-type transistor is connected to a drain of the N-type transistor as an output terminal.

15. A chip, wherein one or more pins of the chip are electrically connected to the electrostatic discharge protection circuit according to claim 1.
